(19) United States
(12) Patent Application Publication
(10) Pub. No.: US 2015/0329687 A1
(43) Pub. Date: Nov. 19, 2015

(54) FIREPROOF POLYAMIDE ARTICLE INCLUDING A COATING FORMED BY PLASMA TREATMENT

(71) Applicants: Hélène Gallou, Vermelles (FR); Maude Jimenez, Lille (FR); Charafeddine Jama, Villeneuve D'ascq (FR); René Delobel, Villeneuve D'ascq (FR)

(72) Inventors: Hélène Gallou, Vermelles (FR); Maude Jimenez, Lille (FR); Charafeddine Jama, Villeneuve D'ascq (FR); René Delobel, Villeneuve D'ascq (FR)

(73) Assignee: RHODIA OPERATIONS, Aubervilliers (FR)

(21) Appl. No.: 13/996,455

(22) PCT Filed: Dec. 20, 2011
(86) PCT No.: PCT/EP2011/073419

§ 371 Date: Oct. 30, 2013

(30) Foreign Application Priority Data
Dec. 21, 2010 (FR) 1060871

(51) Int. Cl. C08J 7/04; C23C 16/50

(52) U.S. Cl. CPC C08J 7/047; C23C 16/50; C08J 2377/06; C08J 2483/04

(57) ABSTRACT

Polyamide articles are described, in particular molded fireproof articles, including a coating deposited using cold plasma. The articles can have excellent flame properties, and can include, in the polyamide matrix, at least one fireproofing system and have such a coating on at least one of the surfaces thereof.

The present invention relates to polyamide-based flame-retardant articles, in particular molded articles, comprising a coating deposited using a cold plasma. These articles, which exhibit excellent flame retardant properties, comprise, in the polyamide matrix, at least one flame retardant system and have such a coating over at least one of the surfaces of said articles.

### PRIOR ART

Compositions based on polyamide resin are used to produce articles by various forming processes, in particular articles molded in various manners. These articles are used in numerous technical fields. Among these, the production of components of electrical or electronic systems is a major application requiring specific properties. Thus, these components have to exhibit superior mechanical properties but also properties of chemical resistance and electrical insulation and especially a high fire resistance.

The flame retardancy of compositions based on polyamide resin has been studied for a very long time. Thus, the main flame retardants used are red phosphorus and halogenated compounds, such as dibromophenols, polybromodiphenyls, polybromodiphenyl oxides and brominated polystyrenes. From about twenty years ago, new flame-retardant categories have been developed, such as nitrogen-containing organic compounds belonging to the category of the triazines, such as melamine or its derivatives, such as melamine cyanurate and more recently melamine phosphates, polyphosphates and pyrophosphates, alone or in combination with organic and/or inorganic phosphonates or phosphinates.

The advantage of this final category of flame retardants lies in the fact that the compounds concerned do not comprise halogens or red phosphorus. This is because flame retardants comprising halogens or red phosphorus can generate toxic gases during the combustion of the polyamide composition or even during the preparation of said composition. However, the amounts of some melamine-based compounds necessary to obtain satisfactory flame retardancy are very high, in particular for the compositions comprising reinforcing fillers in the form of fibers, such as glass fibers. This high concentration of melamine compounds exhibits certain disadvantages, in particular during the manufacture of the composition, such as the production of vapor of the melamine-containing compounds, or during the production of molded articles, such as the blocking of the ventilation pipes and deposits in the molds.

Likewise, the new organic phosphorus-based flame-retardant systems are high in cost and need to be used in a large amount in order to obtain good flame retardant properties.

An excessively high amount of flame retardants in a polyamide matrix furthermore results in a deterioration in its mechanical properties. However, certain applications, and for example structural applications, require high mechanical properties combined with good flame retardant properties

There thus exists a need to prepare flame-retardant polyamide compositions comprising contents of flame retardants, in particular organophosphorus compounds, which are relatively low or, in any case, significantly lower than the content normally used to obtain a good flame retardancy capability.

### INVENTION

The Applicant Company has demonstrated, entirely unexpectedly, that it is possible to produce polyamide articles exhibiting excellent flame retardant properties, while using small amounts of flame retardants, by producing a coating on said polyamide articles by cold-plasma-enhanced chemical deposition.

Thus, one subject of the present invention is a flame-retardant article obtained by forming a polyamide composition comprising at least one flame retardant system, said article comprising, at least over a portion of its surface, a coating produced by cold-plasma-enhanced chemical deposition, very particularly said articles result in a V0 result in the UL94 test on 1.6 mm bars.

Polyamide articles are thus obtained that have a very good flame retardancy and in particular a V0 result in the UL94 test while using small amounts of flame retardants and to thus obtain good mechanical properties; by the presence of a coating produced by plasma-enhanced chemical deposition on said polyimide articles. Indeed, such a coating makes it possible to confer good flame retardant properties on the articles and does not contain environmentally harmful compounds in the combustion products, the latter generally consisting of materials of silica type.

Surface is understood to mean the surface layer of a polyamide article according to the invention. A surface is generally a portion defined by a border or boundaries. A surface can in particular be flat, concave and/or convex, depending on the articles and their complexity.

The article according to the invention is obtained by forming a polyamide-based composition, that is to say a composition comprising at least one polyamide.

The polyamide is selected from the group consisting of polyamides obtained by polycondensation of a linear dicarboxylic acid with a linear or cyclic diamine, such as PA 6.6, PA 6.10, PA 6.12, PA 12.12, PA 4.6, and MXD.6, or between an aromatic dicarboxylic acid and a linear or aromatic diamine, such as polyterephthalamides, polyisophthalamides or polyaramids, and polyamides obtained by polycondensation of an amino acid with itself, it being possible for the amino acid to be generated by the hydrolytic opening of a lactam ring, such as, for example, PA 6, PA 7, PA 11 or PA 12.

The composition of the invention can also comprise copolyamides derived in particular from the above polyamides, or the blends of these polyamides or copolyamides.

The preferred polyamides are polyhexamethylene adipamide, polycaprolactam, or copolymers and blends of polyhexamethylene adipamide and polycaprolactam.

Use is made generally of polyamides with molecular weights which are suitable for injection molding processes, although polyamides with lower viscosities can also be used. Use may also be made of polyamides having higher molecular weights, in particular as regards transformation processes of extrusion or extrusion-blow molding type.

The polyamide matrix can in particular be a polymer comprising star or H macromolecular chains and, if appropriate, linear macromolecular chains. Polymers comprising such star or H macromolecular chains are described, for example, in documents FR 2 743 077, FR 2 779 730, U.S. Pat. No. 5,959,069, EP 0 632 703, EP 0 682 057 and EP 0 832 149.

According to another particular variant of the invention, the polyamide matrix of the invention can be a polymer of random tree type, preferably a copolyamide exhibiting a random tree structure. These copolyamides with a random tree structure and their process of preparation are described in particular in document WO 99/03909. The matrix of the invention can also be a composition comprising a linear thermoplastic polymer and a star, H and/or tree thermoplastic polymer as described above. The matrix of the invention can also comprise a hyperbranched copolyamide of the type of those described in the document WO 00/68298. The composition of the invention can also comprise any combination of linear, star, H and tree thermoplastic polymer and hyperbranched copolyamide as described above.

The composition according to the invention can comprise between 20% and 99% by weight, preferably between 20% and 80% by weight and more preferably between 50% and 70% by weight of polyamide, with respect to the total weight of the composition.

The matrix of the composition can also comprise, in addition to the polyamide, one or more other polymers, in particular thermoplastic polymers

The composition can also comprise reinforcing fillers selected in particular from the group consisting of fibrous fillers, such as glass fibers, and/or inorganic fillers, such as kaolin, talc or wollastonite, or else exfoliable fillers. The fibrous fillers may in particular be glass fibers, carbon fibers, or organic fibers.

The concentration by weight of the reinforcing fillers may advantageously be between 1% and 50% by weight, preferably between 15% and 50% by weight, with respect to the total weight of the composition. Use may in particular be made of a mixture of glass fibers and inorganic fillers, such as wollastonite.

Very particularly, the composition comprises a fibrous fillers/total fillers weight ratio ranging from 0.7 to 1, in particular from 0.9 to 1, very particularly from 0.95 to 1. More particularly still, the composition comprises, as fillers, only fibrous fillers.

Very particularly, the composition comprises a content of fibrous fillers, in particular of glass fibers, carbon fibers and/or organic fibers, and in particular of glass fibers, ranging from 10% to 50% by weight, in particular from 15% to 50% by weight, with respect to the total weight of the composition.

The compositions of the invention can also comprise any additive normally used in polyamide-based compositions used for the manufacture of molded articles. Thus, mention may be made, as examples of additives, of heat stabilizers, U.V. stabilizers, antioxidants, lubricants, pigments, dyes, plasticizers or impact modifiers. By way of example, the antioxidants and heat stabilizers are, for example, alkali metal halides, copper halides, sterically hindered phenolic compounds or aromatic amines. The U.V. stabilizers are generally benzotriazoles, benzophenones or HALSs.

There is no limitation on the types of impact modifiers. It is generally the elastomeric polymers which can be used for this purpose. Examples of suitable elastomers are ethylene/acrylic ester/maleic anhydride copolymers, ethylene/propylene/maleic anhydride copolymers or EPDMs (ethylene-propylene-diene monomers) with optionally a grafted maleic anhydride. The concentration of elastomer by weight is advantageously between 0.1% and 15%, with respect to the total weight of the composition.

The compositions of the invention are obtained by mixing the various constituents, generally in a single- or twin-screw extruder, at a temperature sufficient to keep the polyamide resin as a molten medium. Generally, the mixture obtained is extruded in the form of rods which are cut into pieces in order to form granules. The flame retardants can be added, together or separately, to the polyamide by mixing under hot conditions or under cold conditions.

The addition of the compounds and additives can be carried out by addition of these compounds to the molten polyamide in the pure form or in the form of a concentrated mixture in a resin, such as, for example, a polyamide resin.

The granules obtained are used as raw material to feed processes for the manufacture of articles, such as injection, injection molding, extrusion and extrusion-blow molding processes. The article according to the invention can in particular be an extruded or injected article.

Thus, the composition of the invention is particularly suitable for the manufacture of articles used in the field of electrical or electronic connections, such as components of circuit breakers, switches, connectors or the like.

The flame retardant system according to the present invention can comprise flame retardants of any type, that is to say compounds which make it possible to reduce flame propagation and/or which have flame retardant properties, which are well known to a person skilled in the art. These flame retardants are normally used in flame-retardant compositions and are described in particular, for example, in patents U.S. Pat. No. 6,344,158, U.S. Pat. No. 6,365,071, U.S. Pat. No. 6,211,402 and U.S. Pat. No. 6,255,371, cited here by way of reference.

Advantageously, the flame retardant system comprises at least one flame retardant selected from the group consisting of:
phosphorus-containing flame retardants, such as:
   phosphine oxides, such as, for example, triphenylphosphine oxide, tri(3-hydroxypropyl)phosphine oxide and tri(3-hydroxy-2-methylpropyl)phosphine oxide;
   phosphonic acids or salts thereof or phosphinic acids or salts thereof such as, for example, zinc, magnesium, calcium, aluminum or manganese salts of phosphinic acids, in particular the aluminum salt of diethylphosphinic acid or the zinc salt of dimethylphosphinic acid;
   cyclic phosphonates, such as cyclic diphosphate esters, such as, for example, Antiblaze 1045;
   organic phosphates, such as triphenyl phosphate;
   inorganic phosphates, such as ammonium polyphosphates and sodium polyphosphates;
   red phosphorus, whether, for example, in the stabilized or coated form, as a powder or in the form of masterbatches;
flame retardants of nitrogen-containing organic compound type, such as, for example, triazines, cyanuric acid and/or isocyanuric acid, melamine or derivatives thereof, such as melamine cyanurate, melamine oxalate, phthalate, borate, sulfate, phosphate, polyphosphate and/or pyrophosphate, products condensed from melamine, such as melem, melam and melon, tri(hydroxyethyl) isocyanurate, benzoguanamine, guanidine, allantoin and glycoluril;
flame retardants containing halogenated derivatives, such as:
   bromine derivatives, such as, for example, PBDPOs (polybromodiphenyl oxides), BrPS (polybromostyrene and brominated polystyrene), poly(pentabromobenzyl acrylate), brominated indane, tetradecabromodiphenoxybenzene (Saytex 120), 1,2-bis(pentabromophenyl)ethane or Saytex 8010 from Albemarle, tetrabromobisphenol A and brominated epoxy oligomers. Mention may in particular be made, among brominated derivatives, of polydibromostyrene, such as PDBS-80 from Chemtura, brominated polystyrenes, such as Saytex HP 3010 from Albemarle or FR-803P from Dead Sea Bromine Group, decabromodiphenyl ether (DBPE) or FR-1210 from Dead Sea Bromine Group, octabromodiphenyl ether (OBPE), 2,4,6-tris(2,4,6-tribromophenoxy)-1,3,5-triazine or FR-245 from Dead Sea Bromine Group, poly(pentabromobenzyl acrylate) or FR-1025 from Dead Sea Bromine Group, and epoxy-terminated oligomers or polymers of tetrabromobisphenol A, such as F-2300 and F2400 from Dead Sea Bromine Group;
   chlorinated compounds, such as, for example, a chlorinated cycloaliphatic compound, such as Dechlorane Plus® (sold by OxyChem, see CAS 13560-89-9).

These compounds can be used alone or in combination, sometimes synergistically. Preference is given in particular to a synergistic combination of phosphorus-containing compounds, such as phosphine oxides, phosphonic acids or salts thereof or phosphinic acids or salts thereof, and cyclic phosphonates, with nitrogen-containing derivatives, such as melam, melem, melamine phosphate, melamine polyphosphates, melamine pyrophosphates or ammonium polyphosphates.

The composition can comprise from 5% to 40% by weight of flame retardants, with respect to the total weight of the composition.

Within the context of the use of phosphorus-containing flame retardants, such as phosphinic acids or salts thereof, the composition may comprise from 5% to 20% by weight, more preferably from 5% to 10% by weight, of flame retardants, with respect to the total weight of the composition.

The coating of cold-plasma-enhanced chemical deposition consists in making active species react chemically in a plasma in order to give, in contact with the surface of a substrate, a solid reaction product constituting a coating. This technique makes it possible to obtain deposits at relatively low temperatures and the chemical processes are controlled by the kinetics of the reactions.

The coating of the plasma-enhanced chemical deposition according to the invention may be produced in various ways known to those skilled in the art, in particular by cold-plasma-enhanced polymerization techniques, for example under reduced pressure or atmospheric pressure.

Cold plasma makes it possible to obtain deposits at temperatures between 20° C. and 350° C.

Plasma, also known as the “fourth state of matter” is a macroscopically neutral medium, subjected to a high excitation energy. It is a gas consisting of charged particles, electrons and positive ions, which will react at the surface of materials. Two categories of plasma are mainly distinguished: thermal or hot plasmas which are at the thermodynamic equilibrium and cold plasmas not at equilibrium which are generated at low pressure having a lower degree of ionization. The ions that strike the surface of an article transport energy in kinetic, vibrational or electronic form and the ionization energy is dissipated at the surface by neutralization which results in a production of radicals or of heat.

One of the techniques that uses cold plasma is PECVD (plasma-enhanced chemical vapor deposition) which enables polymerization controlled by cold plasma in a nitrogen flow of a precursor or plasmagen gas.

This technique makes it possible to obtain a thin layer at the surface of a substrate, which is highly crosslinked with good adhesion. Several deposition techniques derived from PECVD are possible depending on the position of the substrate with respect to the discharge, such as in particular post-discharge assisted polymerization. The reactive species, with a long lifetime, are created in the discharge and then move into the reaction chamber as far as the substrate. The separation between the discharge zone and the sample holder improves the control of the formation of the film on the substrate. The post-discharge zone contains atoms, free radicals and molecules in various excitation states with a long lifetime.

PECVD can be modeled by a series of elementary steps:
creation of reactive species in a discharge (ionization, dissociation, etc.);
transport of the reactive species from the source to the substrate;
adsorption of the reactants at the surface;
reaction and growth of the film;
desorption and evacuation of the reaction products.

Cold-plasma-enhanced deposition enables the deposition of inorganic compounds, such as SiO₂, Si₃N₄, SiC, TiO₂, or of organic compounds from specific precursors. Deposits obtained from organosilicon compounds are in particular preferred. These deposits may have an inorganic structure of SiO₂ type, and/or an organic structure of siloxane and/or polysiloxane type, in particular comprising various units such as M, D and/or T units, depending on the pressure, the power or proportion of organosilicon compounds used.

The compounds used for making the coating produced by cold-plasma-enhanced chemical deposition are preferably selected from the group consisting of: tetramethyldisiloxane (TMDSO), hexamethyldisiloxane (HDMSO), octamethylcyclotetrasiloxane (OMCTS), and/or tetraethoxysilane (TEOS).

The results of the gas-phase spectroscopic study, the infrared and Raman spectroscopic analyses of the film and also the determination of the growth rate make it possible to propose a three-step mechanism: an initiation step, a propagation step and a termination step.

The coating on the surface of the article may have a thickness between 1 and 200 μm, preferably between 8 and 20 μm.

The organosilicon coatings are applied over at least a portion of the surface of the article according to the invention. The coating will in particular be applied to the portions of the surface that will be capable of being in contact with high heats, in particular flames, or electrical parts that are operating and that give off high heats.

It is also preferred to only use one or more plasma coatings, in particular without using another type of coating.

The present invention also relates to a process for the manufacture of a flame retardant article, in which a coating is applied by cold-plasma-enhanced chemical deposition over at least a portion of the surface of the article, after having optionally carried out a surface treatment step in order to increase the adhesion between the surface and the coating.

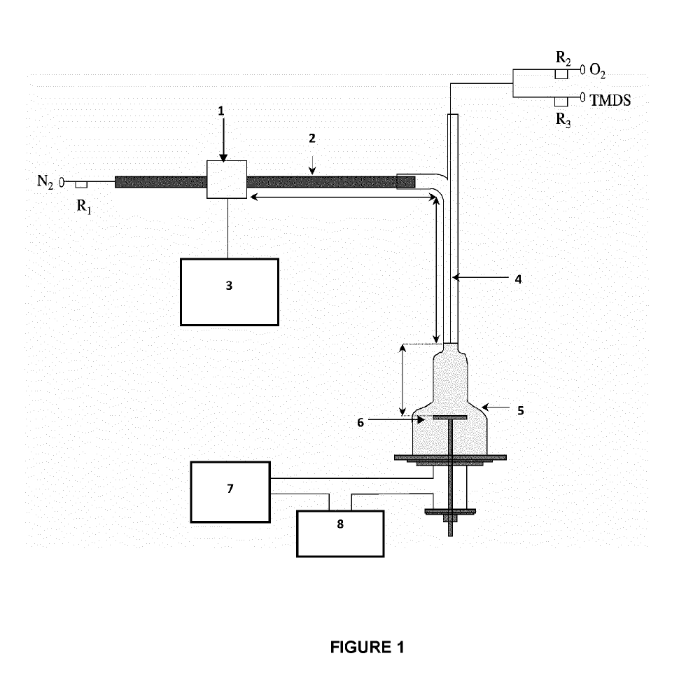

FIG. 1 represents the diagram of the post-discharge plasma device. The microwave generator 3, by means of a coaxial coupler 1, creates the discharge plasma in the quartz tube 2. The pump 7 makes it possible to extract the gas containing the excited species from the discharge zone to the distant post-discharge zone through the coaxial tubular injector 4 to the reactor 5. The reactive gases—the TMDSO monomer and oxygen—are introduced into the Pyrex reactor 5 (height 600 mm and diameter 300 mm). The end of the injector is located 200 or 250 mm from the substrate and 650 mm from the discharge. The circular substrate holder 6, made of aluminum, has a diameter of 150 mm. The flow rates of the oxygen and the TMDSO are kept constant owing to MKS mass flow controllers. The pressure inside the reaction chamber is measured using a Pirani pressure gauge.

A specific language is used in the description so as to facilitate understanding of the principle of the invention. Nevertheless, it should be understood that no limitation of the scope of the invention is envisioned by the use of this specific language. Modifications and improvements can in particular be envisaged by a person conversant with the technical field concerned on the basis of his own general knowledge.

The term “and/or” includes the meanings “and” and “or” and all the other possible combinations of elements connected with this term.

Other details or advantages of the invention will become more clearly apparent in the light of the examples given below purely by way of indication.

### EXPERIMENTAL SECTION

### Materials Used

The tests were carried out with the following constituents:
polyamide 6.6,
glass fibers (Vetrotex 983), denoted by GF,
aluminum phosphinate (OP 1230 from Clariant), denoted by OP1230, and
nanofillers of montmorillonite type, denoted by nanofillers.

The contents of these constituents are presented in table 2 below.

Various types of articles are obtained, according to the subsequent tests to be carried out, by injection molding.

### Deposition Procedure

A PECVD, the diagram of which is represented in FIG. 1, is carried out with the following parameters spread over two levels, a lower level and an upper level, and using TMDSO as organosilicon compound:

TABLE 1

| Parameters | |
|---|---|
| Power of the microwave generator (watts) | 1000 |
| O₂ flow rate (ml/min) | 150 |
| N₂ flow rate (ml/min) | 4500 |
| TDMSO flow rate (ml/min) | 15 |
| Injector-substrate distance (mm) | 200 |
| Pretreatment time (min) | 10 |
| Treatment time (min) | 40 |

An organic film having a thickness of 11.7 μm is obtained at the surface of the polyamide article. The contact angle with distilled water at the surface of the article increases by 20% with respect to the same article that has not been treated by PECVD. No delamination of the organosilicon film is observed with the articles according to the present invention. The FTIR spectrum of the chemical deposit shows that the latter is an essentially polysiloxane structure.

### Fire Resistance Performances

The flame retardant performances of the articles with or without an organosilicon deposit were evaluated using the LOI (limiting oxygen index), the UL94 test with 1.6 mm thick test specimens and cone calorimeter measurements.

The results are mentioned in the following table:

TABLE 2

| | DESCRIPTION | | | | |
|---|---|---|---|---|---|
| | (% by weight | | | | |
| Exam- | relative to the | LOI | UL94 | RHR | Ignition |
| ples | total weight) | (%) | (/1.6 mm) | (kW/m²) | (s) |
| C1 | PA 6.6 (75%) + | 21-22 | NC | 443 | 54 |
| | GF (25%) | | | | |
| C2 | PA 6.6 (67%) + | 30-33 | V1 | 280 | 70 |
| | GF (25%) + | | | | |
| | OP1230 (8%) | | | | |
| C3 | PA 6.6 (75%) + | — | NC | — | — |
| | GF (25%) + | | | | |
| | PECVD deposition | | | | |
| C4 | PA 6.6 (92%) + | — | NC | 400 | 60 |
| | OP1230 (8%) | | | | |
| C5 | PA 6.6 (92%) + | — | NC | — | — |
| | OP1230 (8%) + | | | | |
| | PECVD deposition | | | | |
| C6 | PA 6.6 (90%) + | — | NC | 402 | 62 |
| | OP1230 (8%) + | | | | |
| | nanofillers (2%) | | | | |
| C7 | PA 6.6 (90%) + | — | NC | 325 | 65 |
| | OP1230 (8%) + | | | | |
| | nanofillers (2%) + | | | | |
| | PECVD deposition | | | | |
| 1 | PA 6.6 (67%) + | 34-35 | V0 | 250 | 92 |
| | GF (25%) + | | | | |
| | OP1230 (8%) + | | | | |
| | PECVD deposition | | | | |

The cone calorimeter is a device which makes it possible, inter alia, to access the change in the amount of heat given off by the combustion of the sample, the inflammability, the loss in weight, the opaqueness of the smoke and the levels of CO/CO₂ given off during the test. The sample is placed horizontally and is subjected to a controlled level of irradiance. The test is carried out in an open environment, in the presence of extractors. The samples are subjected, in ambient air, to a heat flux emitted by a truncated cone (heat flux of between 0 and 100 kW/m²), so as not to disturb the flame. The rate of heat release is evaluated following the principle of oxygen consumption calorimetry. Various analyzers coupled to this system make it possible to evaluate the loss in weight, the opaqueness of the smoke (extinction coefficient k) and the contents of CO and CO₂ during the combustion (infrared analyzers). The ignition time is measured by this test.

It is thus observed that the flame retardant articles of the invention comprising, at least on a portion of their surfaces, a cold-plasma-enhanced organosilicon coating have much better flame retardant properties compared to flame retardant polyamide compositions comprising the same proportion of flame retardants. It furthermore appears that the values obtained during Charpy impact tests representing the mechanical properties of said compositions are equivalent in the presence or in the absence of the cold-plasma-enhanced deposition.

1. A flame-retardant article, the article comprising a polyamide composition comprising at least one flame retardant system, wherein the article further comprises, at least over a portion of its surface, a coating produced by cold-plasma-enhanced chemical deposition.

2. The flame-retardant article as defined by claim 1, wherein the composition additionally comprises reinforcing fillers.

3. The flame-retardant article as defined by claim 1, wherein the flame retardant system of the polyamide composition comprises at least one flame retardant selected from the group consisting of: phosphine oxides, phosphonic acids or salts thereof, phosphinic acids or salts thereof, cyclic phosphonates, organic phosphates, inorganic phosphates and red phosphorus.

4. The flame-retardant article as defined by claim 1, wherein the flame retardant system of the polyamide composition comprises at least one flame retardant selected from the group consisting of: triazines, cyanuric acid and/or isocyanuric acid, melamines, melamine oxalate, phthalate, borate, sulfate, phosphate, polyphosphate and/or pyrophosphate, products condensed from melamine, tris(hydroxyethyl) isocyanurate, benzoguanamine, guanidine, allantoin and glycoluril.

5. The flame-retardant article as defined by claim 1, wherein the flame retardant system of the polyamide composition comprises at least one flame retardant selected from the group consisting of: PBDPOs (polybromodiphenyl oxides), BrPS (polybromostyrene and brominated polystyrene), poly(pentabromobenzyl acrylate), brominated indane, tetradecabromodiphenoxybenzene, 1,2-bis(pentabromophenyl)ethane, tetrabromobisphenol A and brominated epoxy oligomers.

6. The flame-retardant article as defined by claim 1, wherein the composition comprises from 5% to 40% by weight of flame retardants, with respect to the total weight of the composition.

7. The flame-retardant article as defined by claim 1, wherein the composition comprises from 1% to 50% by weight of reinforcing fillers, with respect to the total weight of the composition.

8. The flame-retardant article as defined by claim 1, wherein the coating is produced by cold-plasma-enhanced chemical deposition at a temperature of between 20° C. and 350° C.

9. The flame-retardant article as defined by claim 1, wherein the coating is produced by cold-plasma-enhanced polymerization techniques, under reduced pressure or atmospheric pressure.

10. The flame-retardant article as defined by claim 1, wherein the coating is produced by cold-plasma-enhanced chemical deposition via PECVD (plasma-enhanced chemical vapor deposition).

11. The flame-retardant article as defined by claim 1, wherein the chemical deposition has an SiO₂ inorganic structure and/or a siloxane and/or polysiloxane organic structure.

12. The flame-retardant article as defined by claim 1, wherein the coating on the surface of the article has a thickness of between 1 μm and 200 μm.

13. The flame-retardant article as defined by claim 1, wherein the coating on the surface of the article has a thickness of between 8 μm and 20 μm.

14. The flame-retardant article as defined by claim 1, wherein said article is an extruded or injected article.

15. A process for the manufacture of a flame retardant article, the process comprising applying a coating by cold-plasma-enhanced chemical deposition over at least a portion of a surface of the article obtained by forming a polyamide composition comprising at least one flame retardant system, in particular after a surface treatment step has been carried out in order to increase adhesion between the surface and the coating.

16. The process as defined by claim 15, wherein the compounds used for making the coating produced by cold-plasma-enhanced chemical deposition are selected from the group consisting of: tetramethyldisiloxane, hexamethyldisiloxane, octamethylcyclotetrasiloxane, and tetraethoxysilane.

17. The flame retardant article as defined by claim 7, wherein the reinforcing fillers are present in an amount from 15% to 50% by weight.
